(19) United States
(12) Patent Application Publication
(10) Pub. No.: US 2013/0099227 A1
(43) Pub. Date: Apr. 25, 2013

(54) OXIDE SEMICONDUCTOR, THIN FILM TRANSISTOR, AND DISPLAY DEVICE

(71) Applicants: Okifumi Nakagawa, Osaka-shi (JP); Hirohiko Nishiki, Osaka-shi (JP); Yoshimasa Chikama, Osaka-shi (JP); Yoshifumi Ohta, Osaka-shi (JP); Takeshi Hara, Osaka-shi (JP); Tetsuya Aita, Osaka-shi (JP); Masahiko Suzuki, Osaka-shi (JP); Kazuo Nakagawa, Osaka-shi (JP); Michiko Takei, Osaka-shi (JP); Yoshiyuki Harumoto, Osaka-shi (JP); Hinae Mizuno, Yamato-shi (JP)

(72) Inventors: Okifumi Nakagawa, Osaka-shi (JP); Hirohiko Nishiki, Osaka-shi (JP); Yoshimasa Chikama, Osaka-shi (JP); Yoshifumi Ohta, Osaka-shi (JP); Takeshi Hara, Osaka-shi (JP); Tetsuya Aita, Osaka-shi (JP); Masahiko Suzuki, Osaka-shi (JP); Kazuo Nakagawa, Osaka-shi (JP); Yuuji Mizuno, Osaka-shi (JP); Michiko Takei, Osaka-shi (JP); Yoshiyuki Harumoto, Osaka-shi (JP)

(73) Assignee: SHARP KABUSHIKI KAISHA, Osaka-shi, Osaka (JP)

(21) Appl. No.: 13/394,343

(22) PCT Filed: Apr. 22, 2010
(86) PCT No.: PCT/JP2010/057185

§ 371 Date: Oct. 12, 2012

(30) Foreign Application Priority Data
Sep. 11, 2009 (JP) 2009-210712

(51) Int. Cl. H01L 29/786

(52) U.S. Cl. CPC H01L 29/786
USPC 257/43

(57) ABSTRACT

The present invention provides an oxide semiconductor capable of achieving a thin film transistor with excellent electric property, a thin film transistor having a channel layer formed of the oxide semiconductor, and a display device equipped with the thin film transistor. The oxide semiconductor of the present invention is an oxide semiconductor for a thin film transistor, and includes Al, In, Zn, and O as constituent atoms.

### TECHNICAL FIELD

The present invention relates to an oxide semiconductor, a thin film transistor (hereinafter, also referred to as TFT), and a display device. Specifically, the present invention relates to an oxide semiconductor suitable for a TFT, a TFT including a channel layer formed of the oxide semiconductor, and a display device equipped with the TFT.

### BACKGROUND ART

TFTs are widely used in active matrix substrates for display devices such as liquid crystal display devices. Generally, silicon-based materials including polycrystalline silicon, amorphous silicon, or the like are used for channel layers of TFTs. Since semiconductor compounds have a potential to improve electric property of TFTs, such semiconductor compounds have been eagerly developed as a next generation material expected to be replaced with the silicon-based materials.

For example, Patent Documents 1 and 2 disclose an oxide semiconductor containing In, Ga, and Zn as a semiconductor compound for use in a channel layer of a TFT. Patent Document 3 discloses an amorphous oxide semiconductor containing at least one of In, Ga, Al, Fe, Sn, Mg, Ca, Si, and Ge, and has a resistivity of 10⁸ Ω·m. Furthermore, Patent Document 4 discloses an oxide semiconductor containing at least one of In, Zn, and Sn. Patent Document 4 also discloses an amorphous oxide semiconductor containing at least one selected from the group consisting of Ga, Al, Fe, Sn, Mg, Ca, Si, and Ge, as well as In, Zn, and O, and has a conductivity of not less than 10⁻³ S/cm and not more than 10⁻⁷ S/cm.

Patent Document 5 discloses a semiconductor thin film formed of an amorphous film containing zinc oxide and indium oxide having a carrier density of not more than 10⁺¹⁷ cm⁻³, a Hall mobility of not less than 2 cm²/V·sec, and an energy band gap of not less than 2.4 eV. It is also disclosed that the composition satisfying Zn/(Zn+In)=0.51 to 0.80 is preferable. Patent Document 6 discloses a semiconductor device including a channel layer formed of a composite represented by x(Ga₂O₃).y(In₂O₃).z(ZnO) which satisfies conditions of about 0.75≦x/y≦about 3.15 and about 0.55≦y/z≦about 1.70.
Patent Document 1: Japanese Patent Application Publication No. 2007-281409
Patent Document 2: Japanese Patent Application Publication No. 2008-277326
Patent Document 3: Japanese Patent Application Publication No. 2008-235871
Patent Document 4: Japanese Patent Application Publication No. 2008-166716
Patent Document 5: Japanese Patent Application Publication No. 2007-142195
Patent Document 6: US Patent Application Publication 2007/0252147

### DISCLOSURE OF THE INVENTION

### Problems to be Solved by the Invention

Properties of an oxide semiconductor vary depending on the atomic composition ratio (hereinafter, also referred to as “composition”) thereof. Therefore, if a channel layer of a TFT is formed with an oxide semiconductor, the electric property of the TFT may be unstable depending on the composition of the oxide semiconductor. In this manner, oxide semiconductors for TFTs still have a room for improvement in terms of optimization of the composition.

The present invention has been devised in consideration of the aforementioned current situation, and aims to provide an oxide semiconductor which can produce a TFT with excellent electric property, a TFT including a channel layer formed of the oxide semiconductor, and a display device equipped with the TFT.

### Means for Solving the Problem

The present inventors have made various investigations on oxide semiconductors capable of producing TFTs with excellent electric property. Then, the present inventors focused their attention to oxide semiconductors containing Al (aluminum), In (indium), Zn (zinc), and O (oxygen) as constituent atoms. As a result, they have found that TFTs with excellent electric property can be produced by controlling the composition ratio of the In, Al, and Zn in the oxide semiconductors. Accordingly, the present inventors have solved the foregoing problems, and thereby completed the present invention.

Namely, the present invention relates to an oxide semiconductor including Al, In, Zn, and O as constituent atoms for a TFT. The composition ratio of the Al atom in the oxide semiconductor preferably satisfies the inequality: Si/(In +Si+Zn)≦0.5.

Meanwhile, the oxide semiconductor of the present invention including Al, In, Zn, and O as constituent atoms preferably consists of essentially Al, In, and Zn. This structure enables easier production of a TFT with excellent electric property. As used herein, the oxide semiconductor layer consisting of Al, In, Zn, and O refers to an oxide semiconductor layer in which the amount of constituent atoms other than Al, In, Zn, and O is less than 0.1% by weight for the total weight of the oxide semiconductor. The composition of the oxide semiconductor can be checked by Auger Electron Spectroscopy (AES), X-ray photoelectron spectroscopy (XPS), or the like.

In the oxide semiconductor of the present invention, increase in the atomic composition ratio of Al and decrease in the atomic composition ratio of In reduce the mobility of the oxide semiconductor. The oxide semiconductor having a mobility of less than 0.1 cm²/Vs is difficult to be used as a TFT in a display device. For this reason, the composition ratio of the Al atom contained in the oxide semiconductor preferably satisfies the inequality: Al/(In +Al+Zn)≦0.5.

Assuming that the atomic composition ratio of the oxide semiconductor is (In)ₐ(Si)_{b}(Zn)_{c}(O)_{d}, preferably the inequality: d≧(3a/2+3b/2+c)×0.55 is satisfied. This composition can enhance the electric property of a TFT, particularly can reduce the off-current. Moreover, the inequality: d≦(3a/2+3b/2+c)×0.95 is preferably satisfied. This composition can enhance the electric property of a TFT, particularly can increase the on-current.

The present invention also relates to a TFT including a channel layer formed of the oxide semiconductor of the present invention. If a channel layer of a TFT is formed with the oxide semiconductor of the present invention, the TFT can have enhanced electric property as mentioned earlier.

The present invention further relates to a display device including the TFT of the present invention. Since the TFT of the present invention has excellent electric property as mentioned earlier, it can enhance visual quality of the display device. Examples of the display device of the present invention include various kinds of display devices equipped with a TFT array substrate, such as liquid crystal display devices, organic EL display devices, inorganic EL display devices, electronic portal imaging devices, plasma display devices, and field emission display devices.

The aforementioned modes may be employed in appropriate combination as long as the combination is not beyond the spirit of the present invention.

### Effects of the Invention

The oxide semiconductor, the TFT, and the display device of the present invention can provide an oxide semiconductor which enables production of a TFT having excellent electric property, a TFT including a channel layer formed of the oxide semiconductor, and a display device equipped with the TFT.

### BRIEF DESCRIPTION OF THE DRAWINGS

FIG. 1(a) to FIG. 1(e) are each a flow chart showing a production process of an active matrix substrate included in a liquid crystal display device of Embodiment 1.

FIG. 2(a) to FIG. 2(c) are each a flow chart showing a production process of a counter substrate included in a liquid crystal display device of Embodiment 1.

FIG. 3(a) to FIG. 3(e) are each a flow chart showing a production process of an active matrix substrate included in a liquid crystal display device of Embodiment 2.

FIG. 4 is a graph showing a relationship between the component ratio of Al and the mobility of an oxide semiconductor.

FIG. 5 is a graph showing a relationship between the oxygen charging rate and the mobility of an oxide semiconductor.

FIG. 6 is a graph showing a relationship between the oxygen charging rate and the off-current in an oxide semiconductor.

FIG. 7 is a graph showing a relationship between the component ratio of Zn and the etching rate of an oxide semiconductor.

### MODES FOR CARRYING OUT THE INVENTION

The present invention will be mentioned in more detail referring to the drawings in the following Embodiments, but is not limited to these Embodiments. In the drawings shown below, units are described in brackets.

### Embodiment 1

A liquid crystal display device of Embodiment 1 includes an active matrix substrate and a counter substrate. A plurality of TFTs each including an oxide semiconductor as a channel layer are disposed on the active matrix substrate. Red, green and blue color filters are disposed on the counter substrate. The active matrix substrate is attached to the counter substrate with a sealing material. Liquid crystals are filled in between the substrates. Production process of the liquid crystal display device of Embodiment 1 will be described below with reference to drawings.

### (Production Process of Active Matrix Substrate)

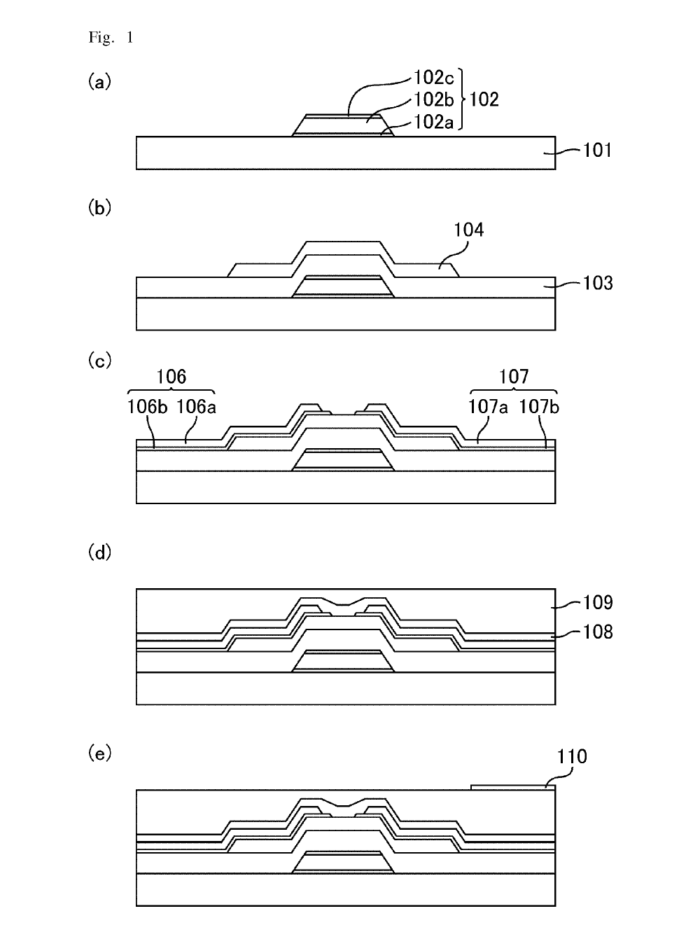

FIG. 1(a) to FIG. 1(e) are each a flow chart showing a production process of an active matrix substrate included in the liquid crystal display device of Embodiment 1.

A method of forming a scanning wiring 102 having a laminate structure consisting of scanning wiring layers 102a, 102b, and 102c is described below with reference to FIG. 1(a).

First, materials of the respective scanning wiring layers 102a, 102b, and 102c are deposited in said order on a glass substrate 101 by a sputtering method to be formed into a laminated film. Thereafter, the laminated film is patterned by a photolithographic method including a wet etching step and a resist-peeling step. Thereby, the scanning wiring 102 having a laminate structure consisting of the scanning wiring layers 102a, 102b, and 102c can be formed. Ti, for example, can be used as the material of the scanning wiring layers 102a and 102c. The thickness of the scanning wiring layers 102a and 102c is, for example, approximately 30 to 150 nm. Al, for example, can be used as the material of the scanning wiring layer 102b. The thickness of the scanning wiring layer 102b is, for example, approximately 200 to 500 nm. In the present embodiment, the scanning wiring 102 has a laminate structure consisting of Ti/Al/Ti. A part of the scanning wiring 102 functions as a gate electrode of the TFT.

Next, methods of forming an insulating layer 103 and an oxide semiconductor layer 104 are described below with reference to FIG. 1(b).

First, the insulating layer 103 is formed by a CVD method such that it covers the glass substrate 101 and the scanning wiring 102. A SiNₓ layer, for example, can be used as the insulating layer 103. The thickness of the insulating layer 103 is, for example, approximately 200 to 500 nm. A part of the insulating layer 103 functions as a gate insulating film of the TFT. Thereafter, material of the oxide semiconductor layer 104 is deposited by a sputtering method to be formed into a film, and the film is patterned by a photolithographic method including a wet etching step and a resist-peeling step. Thereby the oxide semiconductor layer 104 can be formed. A part of the oxide semiconductor layer 104 functions as a channel layer of the TFT. In the present embodiment, an oxide semiconductor film (IAZO film) containing In, Al, Zn, and O is used as the oxide semiconductor layer 104. The thickness of the oxide semiconductor layer 104 is, for example, approximately 10 to 300 nm.

Next, methods of forming a signal wiring 106 having a laminate structure consisting of signal wiring layers 106a and 106b, and a drain electrode 107 having a laminate structure consisting of drain electrode layers 107a and 107b are explained below with reference to FIG. 1(c). Meanwhile, the following describes the case where the material of the signal wiring 106 and that of the drain electrode 107 are the same. However, the material of the signal wiring 106 may be different from the material of the drain electrode 107.

First, the materials of the signal wiring layer 106a and the drain electrode layer 107a are deposited, and then the materials of the signal wiring layer 106b and the drain electrode layer 107b are deposited, respectively, thereon by a sputtering method to form laminated films. Next, the laminated films are patterned by a photolithographic method including a dry etching step and a resist-peeling step. Thereby, the signal wiring 106 having a laminate structure consisting of the signal wiring layers 106a and 106b, and the drain electrode 107 having a laminate structure consisting of the drain electrode layers 107a and 107b can be formed. A part of the signal wiring 106 functions as a source electrode of the TFT. Ti, for example, can be used as the material of the signal wiring layer 106a and the drain electrode layer 107a. The thickness of the signal wiring layer 106a and the drain electrode layer 107a is, for example, approximately 30 to 150 nm. Al, for example, can be used as the material of the signal wiring layer 106b and the drain electrode layer 107b. The thickness of the signal wiring layer 106b and the drain electrode layer 107b is, for example, approximately 50 to 400 nm. In the present embodiment, the signal wiring 106 and the drain electrode 107 each have a laminate structure consisting of Al/Ti. Through the foregoing process, a TFT including the gate electrode, the gate insulating film, the channel layer, the source electrode, and the drain electrode 107 is formed.

Next, methods of forming a protective layer 108 and an interlayer insulating film 109 are described below with reference to FIG. 1(d).

First, material of the protective layer 108 is deposited, and then material of the interlayer insulating film 109 is deposited thereon to be formed into laminated films by a CVD method or a sputtering method. Thereafter, the laminated films are patterned by a photolithographic method including a dry etching step and a resist-peeling step. Thereby, the protective layer 108 and the interlayer insulating film 109 can be formed. A SiOₓ layer, for example, can be used as the protective layer 108. The thickness of the protective layer 108 is, for example, approximately 50 to 300 nm. A photosensitive resin, for example, can be used as the material of the interlayer insulating film 109.

Next, a method of forming a pixel electrode 110 is described below with reference to FIG. 1(e).

First, material of the pixel electrode 110 is deposited by a sputtering method to be formed into a film. Thereafter, the film is patterned by a photolithographic method including a wet etching step and a resist-peeling step. Thereby, the pixel electrode 110 can be formed. ITO (indium tin oxide), for example, can be used as the material of the pixel electrode 110. The thickness of the pixel electrode 110 is, for example, approximately 50 to 200 nm.

Through the foregoing process explained with reference to FIG. 1(a) to FIG. 1(e), an active matrix substrate included in the liquid crystal display device of Embodiment 1 can be produced.

### (Production Process of Counter Substrate)

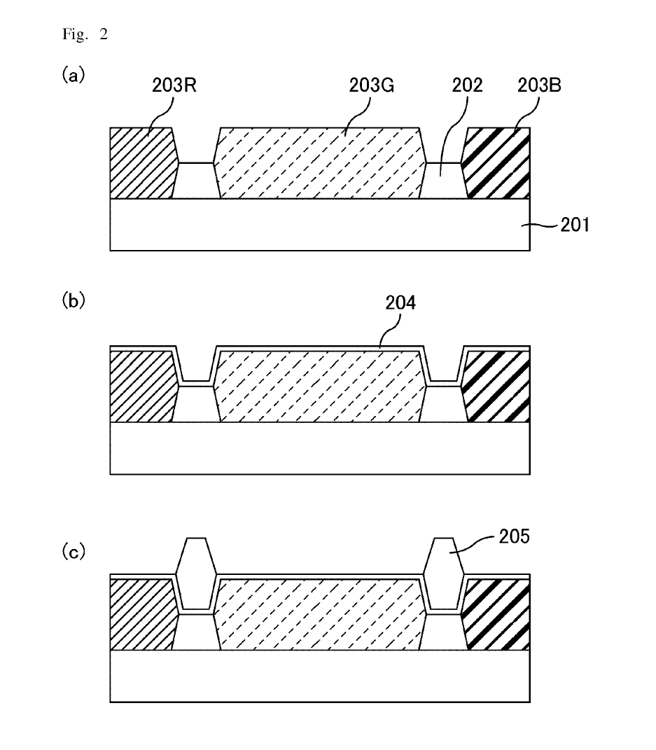

Next, a method of producing a counter substrate included in the liquid crystal display device of the present embodiment is described. FIG. 2(a) to FIG. 2(c) are each a flow chart showing a production process of a counter substrate included in the liquid crystal display device of Embodiment 1.

First, methods of forming a black matrix (BM) 202, a red color filter 203R, a green color filter 203G, and a blue color filter 203B are described below with reference to FIG. 2(a). The BM 202, and the red color filter 203R, the green color filter 203G, and the blue color filter 203B can be formed by patterning a photosensitive resin containing pigments by a photolithographic method. The formation may be performed in the order of forming the BM 202 on a glass substrate 201, and then sequentially forming the red color filter 203R, the green color filter 203G, and the blue color filter 203B on the regions separated by the BM 202. Accordingly, the red color filter 203R, the green color filter 203G, and the blue color filter 203B can each be disposed on the glass substrate 201.

Next, a method of forming a common electrode 204 is described with reference to FIG. 2(b).

First, material of a common electrode 204 is deposited by a sputtering method to be formed into a film. Thereafter, the film is patterned by a photolithographic method including a wet etching step and a resist-peeling step. Thereby, a common electrode 204 can be formed. ITO (indium tin oxide), for example, can be used as the material of the common electrode 204. The thickness of the common electrode 204 is, for example, approximately 50 to 200 nm.

Next, a method of forming a photospacer 205 is described with reference to FIG. 2(c).

The photospacer 205 can be formed by patterning a photosensitive resin by a photolithographic method.

Through the process described with reference to FIG. 2(a) to FIG. 2(c), the counter substrate included in the liquid crystal display device according to Embodiment 1 can be produced.

### (Panel Production Process)

The following will discuss a process of attaching the active matrix substrate and the counter substrate which are produced according to the foregoing process, and a process of filling liquid crystals.

First, an alignment layer is formed on the surface of the active matrix substrate and the surface of the counter substrate by a printing method. Polyimide resins, for example, can be used as the material of the alignment layer.

Next, the sealing material is placed by a printing method on either the active matrix substrate or the counter substrate, followed by dropping of the liquid crystals. Then, the active matrix substrate and the counter substrate are attached to one another.

Thereafter, the substrates attached as above are subjected to dicing to be divided. Accordingly, a liquid crystal display panel included in the liquid crystal display device of the present embodiment can be produced.

Next, standard members such as a driving device are mounted on the liquid crystal display panel produced in the foregoing process so that a liquid crystal display device of the present embodiment can be produced.

Meanwhile, in the foregoing process, the case where the scanning wiring has a laminate structure consisting of Ti/Al/Ti is described. However, the scanning wiring may have a laminate structure consisting of Cu/Ti. Similarly, the drain electrode may have a laminate structure consisting of Cu/Ti.

The BM 202, the red color filter 203R, the green color filter 203G, and the blue color filter 203B may be formed on the active matrix substrate, not on the counter substrate.

Moreover, the display device of the present invention is not limited to liquid crystal display devices, and may be applied for display devices other than liquid crystal display devices.

### Embodiment 2

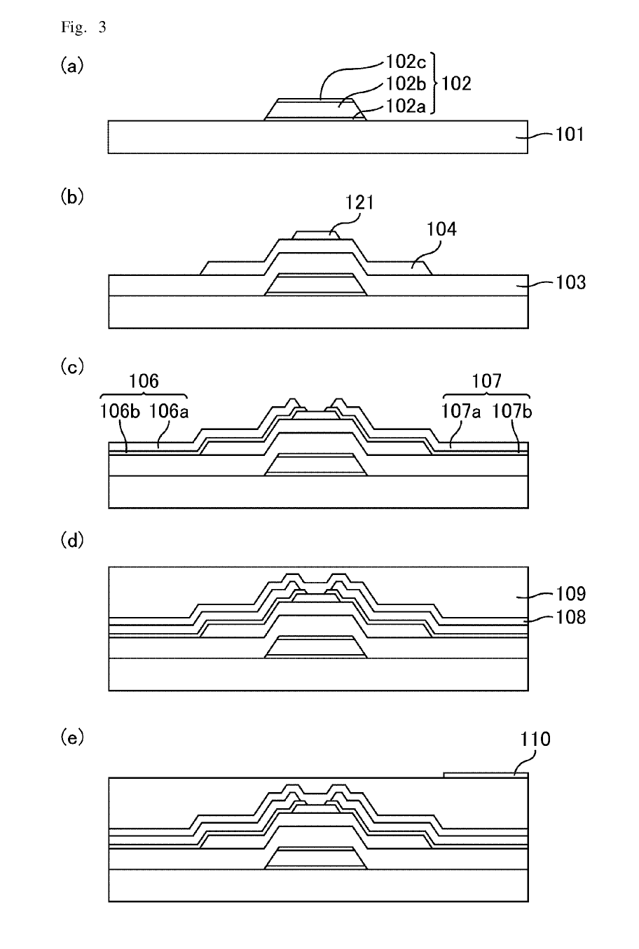

The present embodiment is provided with a layer (channel protecting layer) for protecting a channel layer of a TFT. FIG. 3(a) to FIG. 3(e) are each a flow chart showing a production process of an active matrix substrate included in the liquid crystal display device of Embodiment 2. A method of producing the active matrix substrate having a channel protecting layer is explained hereinbelow.

According to the method explained with reference to FIG. 1(a) and FIG. 1(b), the scanning wiring 102, the insulating layer 103, and the oxide semiconductor layer 104 are formed on the glass substrate 101 as shown in FIG. 3(a) and FIG. 3(b). Then material of a channel protecting layer 121 is deposited by a sputtering method to be formed into a firm. The film is patterned by a photographic method including a dry etching step and a resist-peeling step. Thereby, the channel protecting layer 121 can be formed as shown in FIG. 3(b). SiO₂, for example, can be used as the material of the channel protective layer 121. The thickness of the channel protective layer 121 is, for example, approximately 20 nm to 500 nm.

Thereafter, the process shown in FIG. 3(a) to FIG. 3(e) are performed according to the method described with reference to FIG. 1(a) to FIG. 1(e) so that an active matrix substrate including the channel protecting film 121 can be produced. If the channel protective layer 121 is provided, damages to the oxide semiconductor layer 104 during the production process can be reduced, and also the credibility of the TFT can be enhanced. Moreover, desorption of oxygen from the oxide semiconductor layer 104 can be prevented from occurring during the production process.

The liquid crystal display device of Embodiment 2 has a similar structure as that of the liquid crystal display device of Embodiment 1 except that the channel protection layer 121 is provided. Therefore, explanation of the production method after the process of producing the counter substrate is omitted.

### (Dependency of TFT Properties on Composition Ratio)

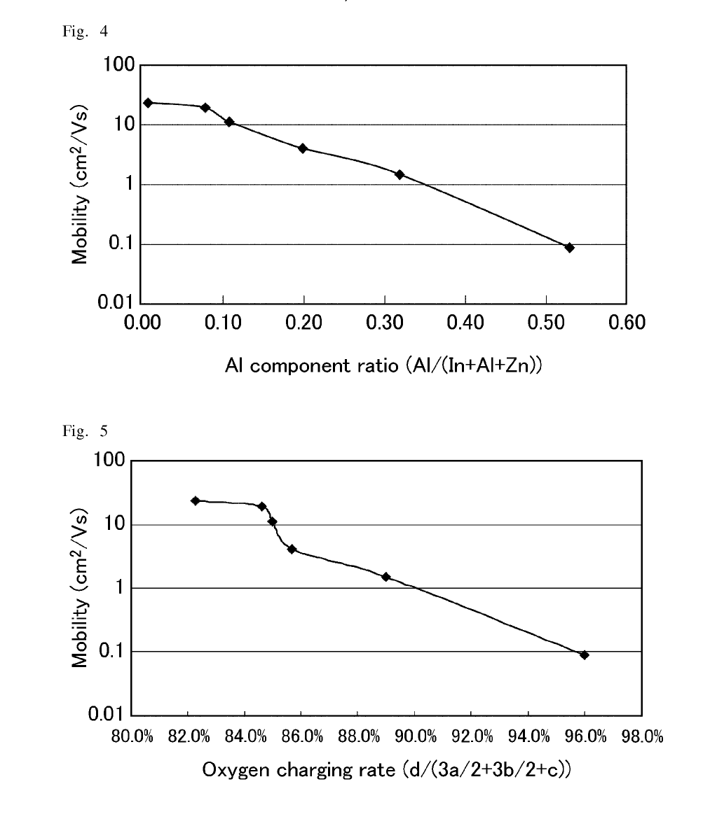

If the composition ratio of the Al atom increases and the composition ratio of the In atom decreases in the oxide semiconductor containing In, Al, Zn, and O, the mobility tends to decrease. FIG. 4 shows a relationship between the composition of an oxide semiconductor including Al, In, Zn, and O and the mobility. In order to allow the TFT to exert sufficient electric property, the mobility is preferably not less than 0.1 cm²/Vs. Based on plural test results, the present inventors have found that, in the case where the composition ratio of the Al atom contained in the oxide semiconductor satisfies the inequality: Al/(In +Al+Zn)≦0.5, the mobility of the oxide semiconductor reaches not less than 0.1 cm²/Vs. In the case where the composition ratio of the Al atom contained in the oxide semiconductor satisfies the inequality: Al/(In +Al+Zn)≦0.5, the oxide semiconductor has been found to have a resistivity of not less than 10³ Ω·cm. More preferably, the composition ratio of the Al atom in the oxide semiconductor satisfies 0.01≦Al/(In +Al+Zn)≦0.5.

If the mobility is not less than 0.1 cm²/Vs, the oxide semiconductor can be sufficiently applied for electric devices including display devices with a low driving frequency such as an electric paper. However, in order to produce display devices for displaying videos such as liquid crystal displays, actually the mobility is required to exceed mobility (approximately 0.5 cm²/Vs) of typical a-Si (amorphous silicon) TFTs. The present inventors have found that such mobility can be achieved if the composition ratio of the Al atom in the oxide semiconductor of the present invention satisfies the inequality: 0.01≦Al/(In +Al+Zn)≦0.35.

If mobility exceeding the mobility (approximately 2.0 cm²/Vs) of a typical micro crystal silicon TFT can be achieved, the cost of the display device can be reduced by including part of driving circuits such as a gate driver or a source driver in the display device. The present inventors have found that this can be achieved by the composition ratio of the Al atom in the oxide semiconductor satisfying the inequality: 0.01 Al/(In +Al+Zn)≦0.25.

If mobility exceeding the mobility (approximately 5.0 cm²/Vs) required for a typical low-molecular organic EL can be achieved, low-molecular organic EL displays can be produced. The present inventors have found that this can be achieved by the composition ratio of the Al atom in the oxide semiconductor satisfying the inequality: 0.01≦Al/(In +Al+Zn)≦0.12.

If mobility exceeding the mobility (approximately 10.0 cm²/Vs) required for a typical polymer organic EL can be achieved, polymer organic EL displays can be produced. The present inventors have found that this can be achieved by the composition ratio of the Al atom in the oxide semiconductor satisfying the inequality: 0.01≦Al/(In +Al+Zn)≦0.1.

Increase in the oxygen charging rate decreases the carrier concentration, which tends to reduce the mobility. As mentioned earlier, the mobility of not less than 0.1 cm²/Vs is preferable to allow the TFT to exert sufficient electric property. In order to achieve this, assuming that the atomic composition ratio of the oxide semiconductor is (In)ₐ(Si)_{b}(Zn)_{c}(O)_{d}, the composition ratio of the O atom preferably satisfies the inequality: d≦(3a/2+3b/2+c)×0.95 as shown in FIG. 5.

Decrease in the oxygen charging rate increases the carrier concentration, which tends to increase off-current. The off-current is preferably not more than 1.0×10⁻¹¹ A to allow the TFT to exert sufficient electric property. In order to achieve this, assuming that the atomic composition ratio of the oxide semiconductor is (In)ₐ(Si)_{b}(Zn)_{c}(O)_{d}, the composition ratio of the O atom preferably satisfies the inequality: d≧(3a/2+3b/2+c)×0.55 as shown in FIG. 6. Meanwhile, the “off-current” refers to a current value between a signal wiring and a drain electrode upon applying a voltage of −10V to a scanning wiring.

Use of Al as the oxide semiconductor material tends to prevent withdrawing of oxygen atoms, and thus the off-current can be reduced. As a result, favorable TFT properties can be achieved. However, excessively large Al composition ratio leads to a high oxygen concentration. The mobility thus decreases, and it becomes difficult to use the oxygen semiconductor as a channel layer, as is understood from the fact that Al₂O₃ is an insulating film. Meanwhile, the main cause of withdrawing of oxygen from the oxide semiconductor supposedly includes dry-etching in the production process and influence of plasma during CVD film formation. Changes in the level of oxygen concentration change the concentration of electrons as carrier, causing changes in the mobility and the off-current.

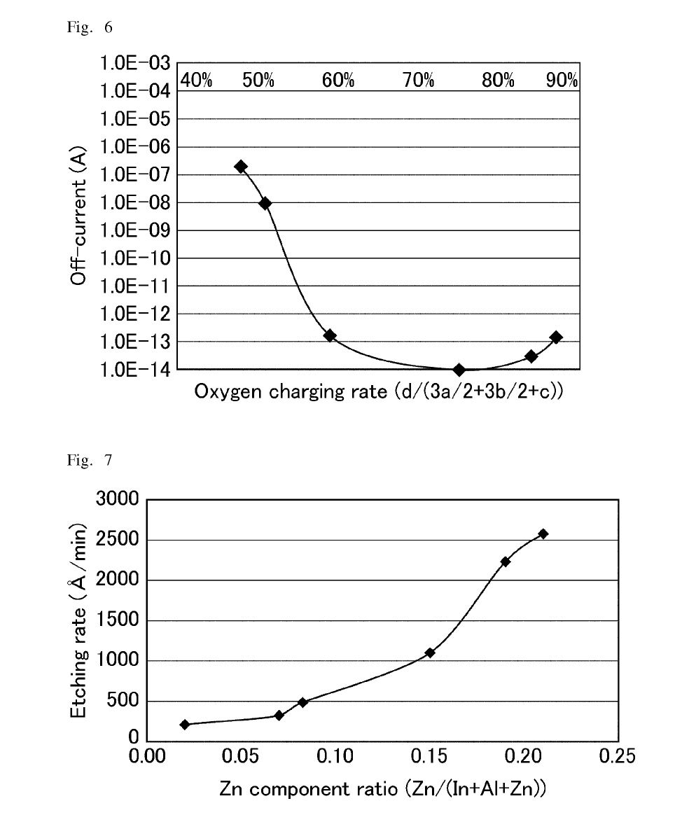

FIG. 7 is a graph showing dependency of the etching rate on the Zn component ratio, namely a relationship between the Zn component ratio in the oxide semiconductor and the etching rate. Oxalic acid was used as an etchant, and the measurement was performed at room temperatures (R.T.). Meanwhile, the etching rate changes when a different etchant is used, or the temperature is changed; however, the tendency of easier etching due to a higher Zn component ratio is maintained. As shown in FIG. 7, the etching rate during wet-etching changes depending on the Zn component ratio. If the etching rate is too high, the etching time becomes too short and the etching may become uncontrollable in the case of machine etching in particular, though the film thickness matters as well. In contrast, if the etching rate is too low, the etching time becomes too long, which is disadvantageous in terms of processing ability in the production. For the aforementioned reasons, the composition ratio of the Zn atom in the oxide semiconductor preferably satisfies 0.04≦Zn (In +Al+Zn)≦0.15 in order to achieve the etching rate of about 300 to 1000 Å/min.

### (Method for Checking the Composition of Oxide Semiconductor)

Examples of methods for checking the composition of the oxide semiconductor include Auger Electron Spectroscopy (AES) and X-ray photoelectron spectroscopy (XPS). In the present embodiment, the composition of the constitution atoms of the oxide semiconductor 104 at a depth of about 20 nm from the surface thereof was measured with an AES analyzer (produced by JEOL Ltd., Model No. JAMP-9500F). Measurement conditions of the AES analysis were set as follows: electron irradiation condition: 5 kV, 5nA; sample: 75 degrees inclination; neutralization condition: Ar ion 10 eV, 1μA; energy resolution of detector: dE/E=0.35%; detection energy step: 1.0 eV. Accordingly, detection peaks of each of the constitution atoms Al, In, Zn, and O were obtained.

Here, the principle of AES analysis is explained. AES analysis is performed by irradiating a measurement target spot of a sample with electron beams, and obtaining a spectrum based on the kinetic energy and the detected intensity of the auger electron emitted from the surface. Since a peak location and a shape of a spectrum are unique to each element, the element is identified based on the peak location and the shape of the spectrum. The concentration of the element in the material is calculated from the intensity (amplitude) of the spectrum. In this manner, the element analysis is performed. Further, since the peak location and the shape of the spectrum are unique to bonding state of the atom, the chemical bonding state (oxidation state, or the like) of the element can also be analyzed.

The Auger electron consists of a very small portion among a huge amount of the detected electron, and thus the accuracy of the detection amount is influenced by backgrounds of low frequency components. In consideration of this, as is generally performed, the spectrum was differentiated to remove the backgrounds of the low frequency components. Then, the composition ratio was calculated from the peak intensities of the respective elements using the sensitivity factor (the values of pure elements accompanied with the device) unique to each element.

The peak intensity and the shape of the spectrum of each element change when the chemical bonding state largely changes. For this reason, the sensitivity factor is desirably corrected to obtain the composition ratio with higher accuracy. Therefore, upon calculation of the composition ratio, the sensitivity factor of each element was adjusted based on the obtained data by performing Rutherford Backscattering Spectrometry (RBS) and Particle Induced X-ray Emission (PIXE).

Each of the embodiments mentioned earlier may be combined in a scope not departing from the principles of the present invention.

The present application claims priority to Patent Application No. 2009-210712 filed in Japan on Sep. 11, 2009 under the Paris Convention and provisions of national law in a designated State, the entire contents of which are hereby incorporated by reference.

### EXPLANATION OF REFERENCE NUMERALS

101, 201: Glass substrate
102a, 102b, 102c: Scanning wiring layer
102: Scanning wiring
103: Insulating layer
104: Oxide semiconductor layer
106a, 106b: Signal wiring layer
106: Signal wiring
107a, 107b: Drain electrode layer
107: Drain electrode
108: Protective layer
109: Interlayer insulating film
110: Pixel electrode
121: Channel protective layer
202: Black matrix (BM)
203R, 203G, 203B: Color filter (CF)
204: Common electrode
205: Photospacer

1: An oxide semiconductor for a thin film transistor comprising Al, In, Zn, and O as constituent atoms.

2: The oxide semiconductor according to claim 1, wherein
the composition ratio of the Al atom in the oxide semiconductor satisfies the inequality: 0.01≦Al/(In +Al+Zn)≦0.5.

3: The oxide semiconductor according to claim 1, wherein
the composition ratio of the Al atom in the oxide semiconductor satisfies the inequality: 0.01≦Al/(In +Al+Zn)≦0.35.

4: The oxide semiconductor according to claim 1, wherein
the composition ratio of the Al atom in the oxide semiconductor satisfies the inequality: 0.01≦Al/(In +Al+Zn)≦0.25.

5: The oxide semiconductor according to claim 1, wherein
the composition ratio of the Al atom in the oxide semiconductor satisfies the inequality: 0.01≦Al/(In +Al+Zn)≦0.12.

6: The oxide semiconductor according to claim 1, wherein
the composition ratio of the Al atom in the oxide semiconductor satisfies the inequality: 0.01≦Al/(In +Al+Zn)≦0.1.

7: The oxide semiconductor according to claim 1, wherein
the composition ratio of the Zn atom in the oxide semiconductor satisfies the inequality: 0.04≦Zn/(In+Al+Zn)≦0.15.

8: The oxide semiconductor according to claim 1, wherein
the composition ratio of the O atom in the oxide semiconductor satisfies the inequality: d≦(3a/2+3b/2+c)×0.95, assuming that the atomic composition ratio of the oxide semiconductor is (In)ₐ(Si)_{b}(Zn)_{c}(O)_{d}.

9: The oxide semiconductor according to claim 1, wherein
the composition ratio of the O atom in the oxide semiconductor satisfies the inequality: d≦(3a/2+3b/2+c)×0.55, assuming that the atomic composition ratio of the oxide semiconductor is (In)ₐ(Si)_{b}(Zn)_{c}(O)_{d}.

10: The oxide semiconductor according to claim 1, wherein
the oxide semiconductor has a resistivity of not less than 10³Ω·cm.

11: A thin film transistor comprising
a channel layer formed of the oxide semiconductor according to claim 1.

12: A display device comprising the thin film transistor according to claim 11.
